(19) United States
(12) Patent Application Publication
(10) Pub. No.: US 2025/0208517 A1
(43) Pub. Date: Jun. 26, 2025

(54) ACIDIC SPIN-ON CARBON (SOC) LAYER FOR EUV LITHOGRAPHY

(71) Applicant: Brewer Science, Inc., Rolla, MO (US)

(72) Inventors: Si Li, Rolla, MO (US); Daniel Patrick Sweat, Rolla, MO (US)

(21) Appl. No.: 18/989,226

(22) Filed: Dec. 20, 2024

Related U.S. Application Data
(60) Provisional application No. 63/612,999, filed on Dec. 20, 2023.

(51) Int. Cl. G03F 7/00; G03F 7/09; H01L 21/027

(52) U.S. Cl. CPC G03F 7/70033; G03F 7/094; H01L 21/027

(57) ABSTRACT

Methods of using an acid-generating, spin-on carbon (SOC) layer for EUV lithography are disclosed. The methods can be used to reduce the dose, scumming, and/or nanobridges induced by insufficient acid at the bottom of a photoresist for both line/space (LS) and contact hole (CH) applications. The methods may improve uniformity in acid compensation at the bottom of the photoresist via bottom-up diffusion of an acid from the acid-generating layer. By utilizing the acid-generating SOC layer under a spin-on silicon hardmask or spin-on glass (SOG), dose reduction has been realized.

### CROSS-REFERENCE TO RELATED APPLICATIONS

The present application claims the priority benefit of U.S. Provisional Patent Application Ser. No. 63/612,999, filed Dec. 20, 2023, entitled ACIDIC SPIN-ON CARBON (SOC) LAYER FOR EUV LITHOGRAPHY, the entirety of which is incorporated by reference herein.

### BACKGROUND

### Field

The present disclosure relates generally to methods of fabricating microelectronic structures.

### Description of Related Art

For extreme ultraviolet (EUV) lithography, dose reduction is a straightforward way to increase throughput. Unfortunately, conventional methods to approach low doses sacrifice roughness or critical dimension (CD) uniformity. Generally, materials are being pursued to achieve lower dose, fewer defects (nanobridges and collapses), lower line width roughness (LWR), and better profile with less scum/top loss. To reduce the dose and the scum/nanobridges induced by insufficient acid at the bottom of the photoresist for both line/space (LS) and contact hole (CH) applications, a method to more effectively compensate the acid at the bottom of the EUV photoresist is needed.

### SUMMARY

The present disclosure broadly provides a method of forming a microelectronic structure. The method comprises forming an acid-generating layer on a substrate surface, or on one or more intermediate layers optionally present on the substrate surface. The acid-generating layer is formed from an acid-generating composition comprising about 50% by weight or greater carbon on a solids basis. The acid-generating composition comprises (i) a polymer and an acid generator; (ii) a polymer including recurring monomers comprising an acid-generating group; or (iii) both (i) and (ii). A hardmask layer is formed on the acid-generating layer, and a photoresist layer is formed on the hardmask layer. At least a portion of the acid-generating layer is exposed to EUV radiation, with an acid being generated in the acid-generating layer during and/or after exposing. The generated acid diffuses through the hardmask layer and to the photoresist layer.

In another embodiment, the disclosure provides a microelectronic structure comprising a substrate having an unpatterned surface and optionally one or more unpatterned intermediate layers other than a dielectric layer on the substrate surface. An acid-generating layer is on the substrate surface, or on the one or more intermediate layers, if present. The acid-generating layer comprises about 50% by weight or greater carbon, based on the weight of the acid-generating layer taken as 100% by weight. The acid-generating layer also comprises (i) a polymer and a photoacid generator; (ii) a polymer including recurring monomers comprising a photoacid-generating group; or (iii) both (i) and (ii). A hardmask layer is on the acid-generating layer, with the hardmask layer comprising less than about 0.5% by weight total of strong acids and generators of strong acids, based on the weight of the hardmask layer taken as 100% by weight. A photoresist layer is on the hardmask layer.

### BRIEF DESCRIPTION OF THE DRAWINGS

FIGS. 1(A)-1(D) provide a schematic illustration (not to scale) of one embodiment of a photolithography method according to the present disclosure;

FIG. 2 is a CD-Dose comparison of SiHM on top of OptiStack® SOC120 material (squares) vs. Formulation 1 (circles);

FIG. 3 shows a dose reduction with increasing acid amount;

FIGS. 4(A)-4(B) show a defect-free depth of focus (DOF) and failure-free range with a prior art spin-on SOC compared to Brewer Science® OptiStack® SOC120 material containing 0% PAG, 5% PAG, and 10% PAG;

FIG. 5 shows biased line width roughness and number of defects comparing an imec SOC, OptiStack® SOC120 material containing 0% PAG, 5% PAG, and 10% PAG;

FIG. 6 shows dose and roughness for lithography after development inspection (ADI) at CD=16 nm; and

FIG. 7 is a graph of CD-dose for hexagonal contact hole (CH) with a 32-nm pitch (mask CD=19 nm×19 nm; ratio of open size (hole) to unopen size was 1:1).

### DETAILED DESCRIPTION

The present disclosure is concerned with acid-generating spin-on carbon (SOC) layers and related methods for use in EUV lithography that allow for lower doses of EUV to be used without sacrificing device quality.

### Acid-Generating Compositions

The acid-generating compositions described herein are preferably SOC compositions that broadly comprise (i) a polymer and an acid generator dispersed or dissolved in a solvent system, (ii) a polymer including recurring monomers comprising an acid-generating group dispersed or dissolved in a solvent system, or (iii) both (i) and (ii).

Suitable polymers are preferably carbon-rich. Carbon-rich polymers typically have at least about 65% carbon atoms, preferably at least about 70% carbon atoms, and more preferably about 70% to about 95% carbon atoms, based upon the total number of atoms in the polymer taken as 100%. This percentage can be calculated based upon the chemical structure of the polymer. Alternatively, the carbon atom and total atom contents can be analyzed and calculated using known analytical equipment, including x-ray fluorescence spectroscopy, auger spectroscopy, and secondary ion mass spectroscopy.

Examples of such polymers include those chosen from polystyrene, functionalized polystyrene derivatives (e.g., poly(4-methylstyrene), poly(vinyl naphthalene)), polysulfones, polyethersulfones, poly(ether ether ketone)s, polycarbonates, epoxies, novolacs, polyimides, polyphenols, polyacrylates, polyphenyl, epoxy cresol novolacs, or combinations thereof. The weight-average molecular weight (Mw) range (as measured by gel permeation chromatography) of the polymer is preferably about 500 g/mol to about 150,000 g/mol, more preferably about 1,000 g/mol to about 80,000 g/mol, and even more preferably from about 1,000 g/mol to about 15,000 g/mol.

The polymer will preferably be present in the acid-generating composition at levels of about 0.001% by weight to about 35% by weight, more preferably about 0.005% to about 20%, more preferably about 0.01% by weight to about 5% by weight, and even more preferably about 0.1% by weight to about 3% by weight, based upon the total weight of the acid-generating composition taken as 100% by weight.

On a solids basis, the polymer will generally be present in the acid-generating composition at levels of about 0.01% by weight to about 35% by weight, more preferably about 0.1% by weight to about 20% by weight, and even more preferably about 0.5% by weight to about 15% by weight, based upon the total weight of the solids in the acid-generating composition taken as 100% by weight. In some embodiments, the polymer will be present in the acid-generating composition at levels of about 50% by weight to about 90% by weight, more preferably about 50% by weight to about 85% by weight, and even more preferably about 50% by weight to about 80% by weight, based upon the total weight of the solids in the acid-generating composition taken as 100% by weight.

Suitable acid generators include photoacid generators (PAGs), thermal acid generators (TAGs), and mixtures thereof. Preferred acid generators will generate a strong acid (i.e., the acid will have a (first) pKa of less than about 0, preferably less than about −3, and more preferably less than about −5).

In some embodiments, the acid generator is a PAG, and preferably an ionic PAG. Suitable PAGs include onium salts, substituted forms of onium salts, triazines, or combinations thereof. Some preferred PAGs are chosen from tris(trifluoromethylsulfonyl) methide, triphenyl sulfonium perfluorosulfonates, alkyl-substituted (preferably C₁-C₆) triphenyl sulfonium perfluorosulfonates nonaflates, tris(4-tert-butylphenyl)sulfonium perfluoro-1-butanesulfonate, N-hydroxynaphthalimide triflate, N-hydroxy-5-norbornene-2,3-dicarboximide perfluoro-1-butanesulfonate), 2-methyl-2-(2′-furylethylidene)-4,6-bis(trichloromethyl)-1,3,5-triazine, 2-[(4′-methoxy)styryl]-4,6-bis(trichloromethyl)-1,3,5-triazine, (4-hydroxyphenyl)dimethylsulfonium hexafluorophosphate, (4-(tert-butyl)phenyl)diphenylsulfonium 2-(4-(adamantan-1-yl)-1,1,2,2-tetrafluorobutoxy)-1,1,2,2-tetrafluoroethane-1-sulfonate, N-hydroxy-5-norbornene-2,3-dicarboximide perfluoro-1-butanesulfonate, triphenylsulfonium salt with tris[(trifluoromethyl)sulfonyl]methane (1:1), [4-(octyloxy)phenyl](phenyl)iodonium hexafluoroantimonate, triphenylsulfonium hexafluoroantimonate, 2-(4-methoxyphenyl)-4,6-bis(trichloromethyl)-1,3,5-triazine, alkyl-substituted (preferably C₁-C₆) triphenyl sulfonium tetrakis(pentafluorophenyl)borates, or combinations thereof. Exemplary commercially available photoacid generators include, but are not limited to, those sold under the names PA-253, PA-225, PA-229, PA-255, TPS-C1, and/or TPS-109, each available from Heraeus Epurio.

The acid generator and/or acid-generating group will typically be included in the SOC composition at levels of about 0.01% by weight to about 30% by weight, preferably about 0.05% to about 20% by weight, more preferably about 0.1% by weight to about 15% by weight, and even more preferably about 0.1% by weight to about 10% by weight, based upon the total weight of the polymer taken as 100% by weight.

The solvent system utilized include one or more solvents chosen from propylene glycol methyl ether acetate (PGMEA), propylene glycol methyl ether (PGME), propylene glycol ethyl ether (PGEE), cyclopentanone, cyclohexanone, anisole, acetophenone, γ-butyrolactone (GBL), or mixtures thereof. The solvent system is preferably utilized at a level of about 50% by weight to about 99% by weight, more preferably about 85% by weight to about 97% by weight, and even more preferably about 90% by weight to about 95% by weight, based upon the total weight of the acid-generating composition taken as 100% by weight. Typical solids contents of the acid-generating composition are about 1% by weight to about 20% by weight, more preferably about 3% by weight to about 15% by weight, and even more preferably about 5% by weight to about 8% by weight, based upon the total weight of the acid-generating composition taken as 100% by weight.

In some embodiments, the acid generator is physically mixed or blended with the polymer (i.e., they are not chemically bonded with one another), while in some embodiments, one or more monomers of the polymer can be functionalized with one or more acid-generating groups. In embodiments where the polymer is functionalized with an acid-generating group(s), the acid generators as described previously can be substituted onto, or bonded with, the monomers that form the polymer, with the preferred polymers being the same ones described previously. In this embodiment, the acid-generating group would be present in similar quantities as described previously with respect to the acid generator. Suitable monomers functionalized with an acid-generating group(s) include those prepared according to U.S. Pat. No. 8,900,792.

The acid-generating composition can also include one or more optional ingredients, including crosslinkers, surfactants, polymers (in addition to the previously described polymer), catalysts, quenchers, additives, or mixtures thereof. For example, in some embodiments, a catalyst may be included in the acid-generating composition. Suitable catalysts include those chosen from quaternary ammonium blocked triflic acid thermal acid generators (e.g., TAG-2689, TAG-2690, and CXC-1821, from King Industries), benzyltriethylammonium chloride, ethyltriphenylphosphonium bromide, tetrabutylphosphonium bromide, or mixtures thereof. When utilized, the catalyst is typically present at levels of about 0.01% by weight to about 15% by weight, preferably about 0.1% by weight to about 10% by weight, and more preferably about 1% by weight to about 5% by weight, based upon the total weight of the polymer taken as 100% by weight. In some embodiments, the acid-generating composition includes both a PAG (preferably in the previously defined acid generator and/or acid-generating group quantities) and a TAG (preferably at the catalyst levels set forth in this paragraph).

In some embodiments, a surfactant may be included in the acid-generating composition to improve coating quality. Nonionic surfactants such as R30N (DIC Corporation, Japan) and FS3100 (The Chemours Company FC, LLC. USA) are suitable surfactants for use herein. In embodiments that include a surfactant, the surfactant is preferably present at levels of about 0.05% by weight to about 0.5% by weight, and more preferably about 0.1% by weight to about 0.3% by weight, based upon the total weight of the polymer taken as 100% by weight.

The acid-generating compositions can be prepared by mixing the above ingredients in the solvent system under ambient conditions. The mixed material is preferably filtered before use, such as with a 0.1-μm or 0.2-μm PTFE filter.

In alternative embodiments, the acid generator can simply be blended with an existing SOC composition, preferably to achieve the previously described acid generator quantities, thus forming the acid-generating composition. Any commercial SOC composition can be used for this purpose, with exemplary SOC materials including OptiStack® SOC110 and SOC120 materials from Brewer Science, Inc., Rolla, MO, US.

Regardless of the preparation procedure, preferred acid-generating compositions comprise about 50% by weight or greater carbon, preferably about 50% by weight to about 99% by weight carbon, preferably about 70% to about 90% by weight carbon, and more preferably about 75% to about 80% by weight carbon, based upon the total solids in the acid-generating composition taken as 100% by weight.

In one or more embodiments, the acid-generating composition is substantially free of blocked isocyanates. That is, the acid-generating composition comprises less than about 0.5% by weight total blocked isocyanates, preferably less than about 0.1% by weight total, and more preferably about 0% by weight total, based on the total weight of the acid-generating composition taken as 100% by weight.

In one or more embodiments, the acid-generating composition is substantially free of isocyanates. That is, the acid-generating composition comprises less than about 0.5% by weight total isocyanates, preferably less than about 0.1% by weight total, and more preferably about 0% by weight total, based on the total weight of the acid-generating composition taken as 100% by weight.

In one or more embodiments, the acid-generating composition is substantially free of TAGs. That is, the acid-generating composition comprises less than about 0.5% by weight total TAGs, preferably less than about 0.1% by weight total, and more preferably about 0% by weight total, based on the total weight of the acid-generating composition taken as 100% by weight.

In some embodiments, the acid-generating compositions consist essentially of, or even consist of, the polymer (e.g., a carbon-rich polymer) and the acid generator (separately mixed and/or as a functional group on the polymer) dispersed or dissolved in a solvent system. In other embodiments, the acid-generating compositions consist essentially of, or even consist of, the polymer (e.g., a carbon-rich polymer) and the acid generator (separately mixed and/or as a functional group on the polymer) dispersed or dissolved in a solvent system, along with one, two, three, four, or all five of a crosslinker(s), surfactant(s), additional polymer(s), catalyst(s), and/or other additive(s).

### Methods of Using Acid-Generating Compositions

In more detail, the present invention provides a method of forming a microelectronic structure that is suited well for lithography, and particularly EUV lithography. In the inventive method, a substrate having a surface is provided. Any microelectronic substrate can be utilized. The substrate is preferably a semiconductor substrate, such as silicon, SiGe, SiO₂, Si₃N₄, SiON, aluminum, tungsten, tungsten silicide, gallium arsenide, germanium, tantalum, tantalum nitride, Ti₃N₄, hafnium, HfO₂, ruthenium, indium phosphide, coral, black diamond, glass, or mixtures of the foregoing. Optional intermediate layers may be formed on the substrate prior to processing. The substrate can have a planar surface, or it can include topographic features (via holes, trenches, contact holes, raised features, lines, etc.). As used herein, “topography” refers to the height or depth of a structure in or on a substrate surface.

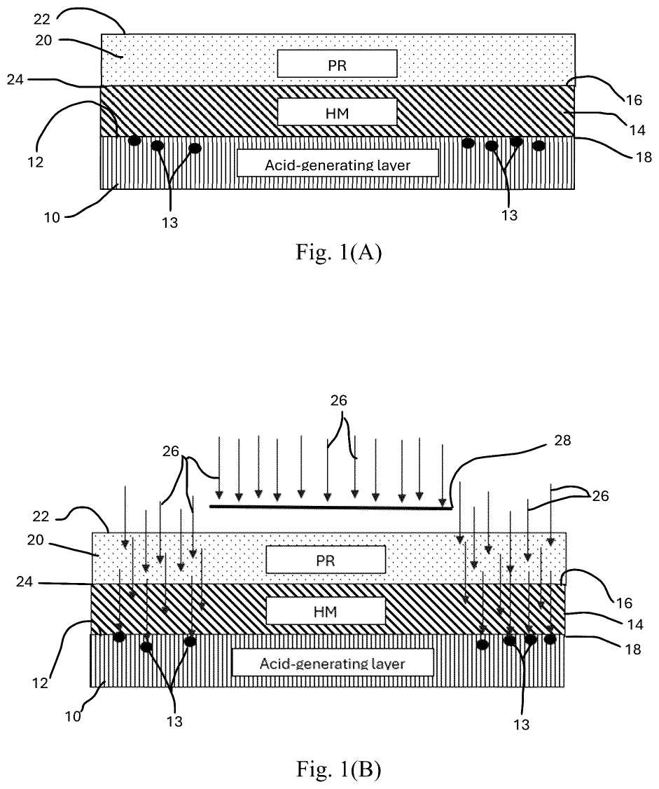

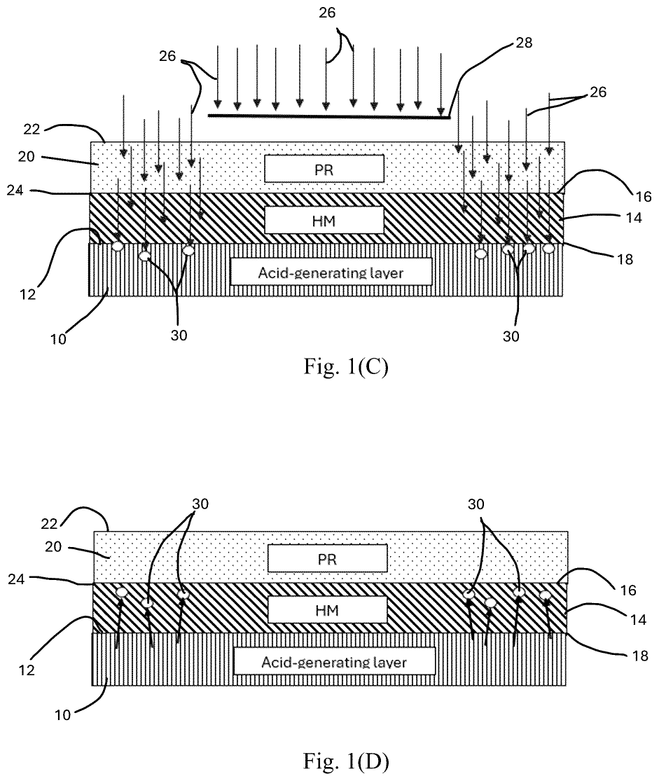

Referring to FIG. 1(A), a layer of the previously described acid-generating composition is formed on the substrate (not shown), or on the uppermost layer of any intermediate layers (not shown), to form an acid-generating layer 10 having an upper surface 12. If the acid-generating layer 10 is applied to an intermediate layer, it is preferred that this intermediate layer is not a planarizing layer. That is, the intermediate layer on which the acid-generating composition is applied preferably did not undergo any physical or chemical alterations after that intermediate layer was formed. For example, it is preferable that this intermediate layer was not subjected to any sort of planarizing steps (i.e., no develop back, thermal reflow, contact planarizing, or other planarizing steps). Additionally or alternatively, it is preferred that any intermediate layer to which the acid-generating layer 10 is applied is a nonpatterned layer and/or is not photosensitive (i.e., cannot be patterned directly by exposure to EUV radiation). The nonpatterned layer may have areas of different composition and/or may not be completely planar; that is, the nonpatterned layer may contain features or topography of less than about 50 nm in height, more preferably less than about 25 nm in height, and even more preferably less than about 5 nm in height.

In some embodiments, any intermediate layer on which the acid-generating composition is applied is substantially free of acids and/or acid generators. That is, this intermediate layer comprises less than about 0.5% by weight total of acids, photoacid generators, and/or thermal acid generators, preferably less than about 0.1% by weight total, and more preferably about 0% by weight total, based on the total weight of the intermediate layer taken as 100% by weight.

In some embodiments, any intermediate layer on which the acid-generating composition is applied is not a dielectric layer. In other words, that intermediate layer preferably has a dielectric constant of greater than 3.9, preferably greater than about 4, and more preferably greater than about 4.5. Examples of dielectric layers include fluorinated silicate glass, amorphous-fluorinated carbon, fluorinated polyimides, fluorinated polyarylene ethers, and/or parylene-F.

Regardless of the presence of and/or type of any intermediate layers, the acid-generating layer 10 can be formed by any known application method, with one preferred method being spin-coating the acid-generating composition at speeds from about 1,000 rpm to about 3,000 rpm, preferably from about 1,300 rpm to about 1,700 rpm, for a time period of from about 20 seconds to about 180 seconds, preferably from about 45 seconds to 120 seconds. Preferably, the acid-generating composition has good spin bowl compatibility, that is, it will not react or form a precipitate with common photoresist solvents such as PGME, PGMEA, ethyl lactate, cyclohexanone, and/or combinations thereof.

After the acid-generating composition is applied, it is preferably heated to a temperature of about 100° C. to about 350° C., and more preferably about 160° C. to about 250° C., for a time period of about 30 seconds to about 120 seconds, and preferably about 45 seconds to about 60 seconds, to evaporate solvents. During application of the acid-generating composition and/or during baking of the applied acid-generating composition to form acid-generating layer 10, the acid generator and/or acid-generating groups (collectively numbered as 13 in FIG. 1) will diffuse or migrate towards upper surface 12 of acid-generating layer 10. Preferably, the acid generator and/or acid-generating groups 13 will be substantially uniformly distributed near and/or at upper surface 12 of acid-generating layer 10.

The thickness of the formed acid-generating layer 10 after baking is preferably about 10 nm to about 120 nm, more preferably about 20 nm to about 100 nm, and even more preferably about 40 nm to about 60 nm, as measured by ellipsometry.

The acid-generating layers 10 formed preferably comprise greater than about 75% by weight carbon, preferably greater than about 80% by weight carbon, and more preferably from about 85% to about 90% by weight carbon, based upon the total weight of the acid-generating layer taken as 100% by weight. The contact angle of the acid-generating layers 10 formed will preferably have a water contact angle of from about 50° to about 85°, more preferably from about 60° to about 80°, as determined by an AST Optima (B5RM5208-143) contact angle measurement tool.

In one or more embodiments, the acid-generating layer 10 is substantially free of blocked isocyanates. That is, the acid-generating layer 10 comprises less than about 0.5% by weight total blocked isocyanates, preferably less than about 0.1% by weight total, and more preferably about 0% by weight total, based on the total weight of the acid-generating layer taken as 100% by weight.

In one or more embodiments, the acid-generating layer 10 is substantially free of isocyanates. That is, the acid-generating layer 10 comprises less than about 0.5% by weight total isocyanates, preferably less than about 0.1% by weight total, and more preferably about 0% by weight total, based on the total weight of the acid-generating layer taken as 100% by weight.

A hardmask layer 14 having an upper surface 16 may be formed on the surface 12 of acid-generating layer 10, creating an interface 18 between acid-generating layer 10 and hardmask layer 14. Preferably, the hardmask layer 14 is formed on the acid-generating layer 10 without any physical or chemical alterations to the acid-generating layer 10 taking place after that acid-generating layer 10 is formed. For example, after the acid-generating layer 10 is formed, it is preferably not subjected to any sort of planarizing steps (i.e., no develop back, thermal reflow, contact planarizing, or other planarizing steps) and/or to any sort of UV curing or other UV exposure steps.

Hardmask compositions for forming the hardmask layer 14 will generally comprise a polymer dissolved or dispersed in a solvent system, along with one or more of the following optional ingredients: surfactants, acid or base catalysts, and/or crosslinkers. Preferred hardmask compositions are inorganic, and commercially available hardmask compositions can be used, with suitable hardmask layers 14 being metal-based and/or silicon-containing materials. Silicon-containing materials are preferably high-silicon-content materials (about 30% by weight or greater silicon, and more preferably about 35% by weight or greater silicon), and such materials typically include silanes, siloxanes, silsesquioxanes, silicon oxynitride, silicon nitride, polysilicon, and/or amorphous silicon. Any hardmask layer 14 with a high etch bias relative to the underlying layers would be suitable, with preferred such compositions comprising a copolymer and/or homopolymer of monomers chosen from phenethyltrimethoxysilane (PETMS), tetraethoxysilane (TEOS), methyltrimethoxysilane, phenyltrimethoxysilane, methyltrimethoxysilane (MTMS), ethyltrimethoxysilane (ETMS), (3-glycidyoxypropyl)triethoxysilane, 2-(3,4-epoxycyclohexyl)ethyltrimethyoxysilane (ECHTMS), phenyltrimethoxysilane (PTMS), 2-(carbomethoxy)ethyltrimethoxysilan (CarboTMS), (1,3-Di-2-propen-1-yl)-5-(([3-triethoxysilylpropyl])-(1,3,5-triazine-2,4,6 (1H,3H,5H)-trione) (DAICATEOS), vinyl trimethoxysilane (VTMS), (3-triethoxysilyl)propylsuccinic anhydride (TEOSPSA), 2-cyanoethyltrimethoxysilane, or combinations thereof. Preferred hardmask compositions will preferably have solids contents of about 0.1% to about 70%, more preferably about 0.5% to about 10%, and even more preferably about 0.5% to about 1% by weight, based upon the total weight of the composition taken as 100% by weight.

The hardmask layer 14 can be formed from the hardmask composition by conventional application methods, such as chemical vapor deposition (CVD) or plasma-enhanced chemical vapor deposition (PECVD). Another suitable method involves spin-coating at speeds of about 1,000 to about 5,000 rpm, and preferably from about 1,250 to about 1,750 rpm, for a time period of from about 30 to about 120 seconds, and preferably from about 45 to about 75 seconds. After the hardmask composition has been coated onto the acid-generating layer 10, it is preferably heated to a temperature of about 100° C. to about 300° C., and more preferably from about 150° C. to about 250° C., for a time period of about 30 seconds to about 120 seconds, and preferably from about 45 seconds to about 60 seconds, to evaporate solvents, thus forming the hardmask layer 14.

The thickness of the hardmask layer 14 after baking (as measured by ellipsometry) is preferably from about 5 nm to about 50 nm, more preferably from about 5 nm to about 40 nm, and even more preferably from about 10 nm to about 30 nm. The hardmask layer 14 should have an etch rate at least about 0.75 times that of the photoresist in a fluorine-rich plasma atmosphere and at least about 5 times slower than the carbon-rich acid-generating layer 10 in an oxygen-rich plasma etch atmosphere.

In some embodiments, the hardmask layer 14 is substantially free of acids and/or acid generators. That is, the hardmask layer 14 comprises less than about 0.5% by weight total of acids, photoacid generators, and/or thermal acid generators, preferably less than about 0.1% by weight total, and more preferably about 0% by weight total, based on the total weight of the hardmask layer 14 taken as 100% by weight.

In some embodiments, the hardmask layer 14 is substantially free of strong acids and/or generators of strong acids but may include one or more weak acids. That is, the hardmask layer 14 comprises less than about 0.5% by weight total of strong acids and/or generators of strong acids, preferably less than about 0.1% by weight total, and more preferably about 0% by weight total, based on the total weight of the hardmask layer 14 taken as 100% by weight. As used herein, strong acids have a (first) pKa of less than about 0, preferably less than about −3, and more preferably less than about −5, and weak acids have a (first) pKa of greater than about 1, preferably greater than about 2, and more preferably greater than about 4.

In the same or different embodiments, the hardmask layer 14 is not acid sensitive. As used herein, “acid sensitive,” means that groups, monomers, and/or polymers in the layer will undergo a chemical change upon exposure to an acid. For example, a crosslinking or decrosslinking reaction may be initiated upon exposure to an acid. As another example, a deprotecting reaction might be initiated upon exposure to an acid. A layer that is not acid sensitive will not experience these or other chemical changes as a result of exposure to an acid.

In some embodiments, the hardmask layer 14 is substantially free of phenolic resins. That is, the hardmask layer 14 comprises less than about 0.5% by weight total of phenolic resins, preferably less than about 0.1% by weight total, and more preferably about 0% by weight total, based on the total weight of the hardmask layer 14 taken as 100% by weight.

After the hardmask layer 14 is applied, a photoresist material can be applied to the upper surface 16 of hardmask layer 14 to form a photoresist layer 20 having an upper surface 22, thus creating an interface 24 between hardmask layer 14 and photoresist layer 20. Preferably, the photoresist layer 20 is formed on the hardmask layer 14 without any physical or chemical alterations to the hardmask layer 14 taking place after that hardmask layer 14 is formed. For example, after the hardmask layer 14 is formed, it is preferably not subjected to any sort of planarizing steps (i.e., no develop back, thermal reflow, contact planarizing, or other planarizing steps). Additionally or alternatively, it is preferred that the hardmask layer 14 is not photosensitive (i.e., cannot be patterned directly by exposure to EUV radiation).

The photoresist layer 20 can be formed by any conventional method, with one preferred method being spin coating the photoresist composition at speeds of about 500 rpm to about 3,000 rpm (preferably about 1,000 rpm to about 2,000 rpm) for a time period of about 15 seconds to about 120 seconds (preferably about 30 seconds to about 60 seconds). The photoresist layer 20 is then optionally post-application baked (“PAB”) at a temperature of preferably about 100° C. to about 250° C., and more preferably about 160° C. to about 205° C., for time periods of about 30 seconds to about 60 seconds. The thickness (as measured by ellipsometry) of the photoresist layer 20 after baking will typically be about 20 nm to about 60 nm, preferably about 30 nm to about 50 nm, and more preferably about 30 nm to about 45 nm.

Referring to FIG. 1(B), the photoresist layer 20 is subsequently patterned by exposure to radiation 26 (e.g., EUV radiation, typically about 13.5 nm wavelength) at a dose of about 10 mJ/cm² to about 120 mJ/cm², preferably about 20 mJ/cm² to about 110 mJ/cm², and more preferably about 35 mJ/cm² to about 90 mJ/cm². More specifically, the photoresist layer 20 is exposed using a mask 28 positioned above the upper surface 22 of the photoresist layer 20. The mask 28 has areas designed to permit the radiation 26 to reflect from the mask and contact the upper surface 22 of the photoresist layer 20. The remaining portions of the mask 28 are designed to absorb the light to prevent the radiation 26 from contacting the surface of the photoresist layer 20 in certain areas. Those skilled in the art will readily understand that the arrangement of reflecting and absorbing portions is designed based upon the desired pattern to be formed in the photoresist layer 20 and ultimately in the substrate or any intermediate layers.

The radiation 26, will pass through the photoresist layer 20 and across interface 24, as well as to and through the hardmask layer 14, to and/or across the interface 18, ultimately contacting the acid-generating groups 13 distributed at and/or near the upper surface 12 of acid-generating layer 10 (FIG. 1(B)). In embodiments where the acid-generating groups 13 are photoacid-generating groups, those photoacid-generating groups will generate an acid 30 in those areas where the photoacid-generating groups were exposed to radiation 26 (FIG. 1 (C)). After exposure, the photoresist layer 20 is preferably subjected to a post-exposure bake (“PEB”) at a temperature of about 60° C. to about 150° C., and preferably about 80° C. to about 120° C., for time periods of about 30 seconds to about 60 seconds.

During exposure and/or during the PEB, the acid 30 will diffuse across interface 18, passing through the hardmask layer 14, towards upper surface 16 of hardmask layer 14 (FIG. 1(D)). The acid 30 eventually migrates to interface 24, causing the polymer in the photoresist layer 20 to crosslink in the areas exposed to the acid 30, or conversely, to deprotect and/or decrosslink in the areas exposed to the acid 30, depending on whether a positive tone or negative tone photoresist layer 20 is utilized, thus compensating for insufficient acid at the bottom of photoresist layer 20.

It will be appreciated that the acid-generating layers 10 and processes described herein lower the radiation dose required to carry out the necessary photopatterning of the photoresist layer 20. Preferably, the required dose will be at least about 3% less than the dose required using the same composition without the acid generator or acid-generating group (e.g., 97 mJ/cm² with the acid-generating layer instead of 100 mJ/cm² for the same layer without an acid generator or acid-generating group). More preferably, the required dose will be at least about 5% less than the dose required using the same composition without the acid generator or acid-generating group, and even more preferably at least about 10% less than the required dose using the same composition without the acid generator or acid-generating group. Advantageously, these decreased doses can be achieved without sacrificing quality and without disrupting the process window. For example, the LWR/LER, collapse/bridge margin, and preferably both remain equivalent to (or even better than) that of the same SOC composition without an acid generator or acid-generating group while requiring a lower EUV dose to size. This is particularly advantageous when chemically amplified resists (CAR) are utilized as EUV dose reduction with CAR resists has proven to be particularly difficult.

The photoresist layer 20 is then contacted with a developer to form the pattern (not shown). Depending upon whether the photoresist used is positive-working or negative-working, the developer will either remove the exposed portions of the photoresist layer 20 or remove the unexposed portions of the photoresist layer 20 to form the pattern. The pattern is then transferred to the hardmask layer 14, the acid-generating layer 10, any present intermediate layers, and finally the substrate. This pattern transfer can take place via plasma etching (e.g., CF₄ etchant, O₂ etchant) or a wet etching or developing process.

Additional advantages of the various embodiments will be apparent to those skilled in the art upon review of the disclosure herein and the working examples below. It will be appreciated that the various embodiments described herein are not necessarily mutually exclusive unless otherwise indicated herein. For example, a feature described or depicted in one embodiment may also be included in other embodiments but is not necessarily included. Thus, the present disclosure encompasses a variety of combinations and/or integrations of the specific embodiments described herein.

As used herein, the phrase “and/or,” when used in a list of two or more items, means that any one of the listed items can be employed by itself or any combination of two or more of the listed items can be employed. For example, if a composition is described as containing or excluding components A, B, and/or C, the composition can contain or exclude A alone; B alone; C alone; A and B in combination; A and C in combination; B and C in combination; or A, B, and C in combination.

The present description also uses numerical ranges to quantify certain parameters relating to various embodiments. It should be understood that when numerical ranges are provided, such ranges are to be construed as providing literal support for claim limitations that only recite the lower value of the range as well as claim limitations that only recite the upper value of the range. For example, a disclosed numerical range of about 10 to about 100 provides literal support for a claim reciting “greater than about 10” (with no upper bounds) and a claim reciting “less than about 100” (with no lower bounds).

### EXAMPLES

The following examples set forth methods in accordance with the disclosure. It is to be understood, however, that these examples are provided by way of illustration, and nothing therein should be taken as a limitation upon the overall scope.

### Example 1

### Formulation 1

In this Example, 95.806 grams of OptiStack® SOC120W material (a spin-on-carbon material available from Brewer Science, Inc., Rolla, MO, US) were mixed overnight on a roller at room temperature with 0.8867 gram of PA-253 (a photoacid generator available from Heraeus Epurio, LLC, US), 0.7566 gram of propylene glycol methyl ether (PGME; FujiFilm UltraPure Solutions, Inc., US), and 2.551 grams propylene glycol monomethyl ether acetate (PGMEA; FujiFilm UltraPure Solutions, Inc., US).

### Example 2

### Film-Forming Characteristics of Formulation 1

The as-prepared formulation from Example 1 was coated on a silicon wafer by spin-coating at 1,500 rpm for 60 seconds, followed by baking at 205° C. for 60 seconds on a hot plate. The carbon-rich layer showed uniform thickness and good coating quality. The thickness of the carbon-rich layer was measured using a Film Sense FS-RT300 Ellipsometer. The average thickness of 25 points on the wafer was 56.93 nm±0.92.

The coating was evaluated using a solvent stripping test, where PGME was puddled on the SOC layer for 30 seconds followed by a spin-dry at 1,500 rpm. This solvent stripping test was repeated using PGMEA in place of PGME. The acid-generating, carbon-rich layer thicknesses before and after stripping were measured using an M-2000 Ellipsometer (J. A. Woollam Co., Lincoln, NE). Stripping was less than 3% of the original thickness.

### Example 3

### Lithography Testing of Formulation 1

The as-prepared formulation from Example 1 was coated on a silicon wafer by spin-coating at 1,500 rpm for 60 seconds, followed by baking at 205° C. for 60 seconds on a hot plate. An experimental silicon hardmask (Brewer Science, Inc., Rolla, MO) was coated on top of baked acid-generating carbon-rich layer by spin-coating at 1,500 rpm for 60 seconds followed by baking at 205° C. for 60 seconds. A resist (Pentaline, a positive-tone development, CAR resist available from TOK, Japan) was coated on top of baked silicon hardmask by spin-coating at 1,500 rpm for 60 seconds, followed by baking at 205° C. for 60 seconds.

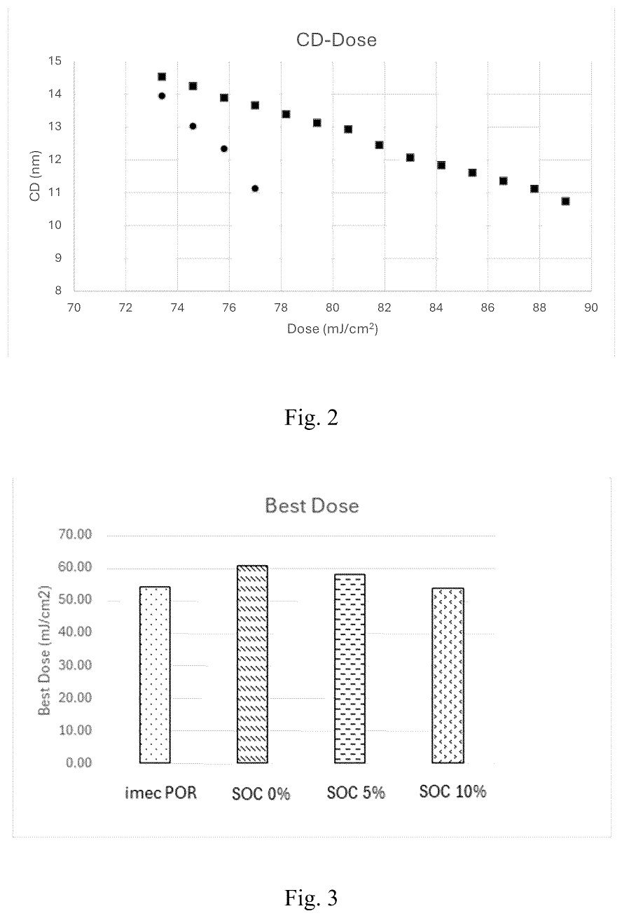

EUV lithography was performed at IMEC using an NXE3400 scanner system (ASML), followed by a post-exposure bake (PEB) at 90° C. for 60 seconds. As shown in FIG. 2, ˜6% dose reduction was achieved with Formulation 1 at L13.

### Example 4

### Formulation 2

In this Example, 98.2811 grams of OptiStack® SOC120W material was mixed with 0.2357 gram of PA-253, 0.1841 gram of PGME, and 0.7416 grams PGMEA on a roller at room temperature.

### Example 5

### Formulation 3

In this Example, 99.8804 grams of OptiStack® SOC120W material was mixed with 0.1136 gram of PA-253, 0.0016 gram of PGME, and 0.0062 grams PGMEA on a roller at room temperature.

### Example 6

### Lithography Comparison of Formulations From Examples 1, 4, and 5

The as-prepared formulation from Examples 1, 4, and 5 were coated on separate silicon wafers having a 60-nm SiN coating by spin-coating at 1,500 rpm for 60 seconds, followed by baking at 205° C. for 60 seconds on a hot plate. An experimental silicon hardmask based on OptiStack® HM710 material (Brewer Science, Inc., Rolla, MO) was coated on top of each baked acid-generating, carbon-rich layer by spin-coating at 1,500 rpm for 60 seconds followed by baking at 205° C. for 60 seconds. Finally, a resist (Pentaline) was coated on top of each baked silicon hardmask layer by spin coating at 1,500 rpm for 60 seconds, followed by baking at 205° C. for 60 seconds.

EUV lithography was performed at IMEC using an NXE3400 scanner system, followed by a PEB at 90° C. for 60 seconds. As shown in FIG. 3, the required dose was reduced by the addition of 5% acid (based on polymer solids) to the SOC, and further reduced by the addition of 10% acid (based on polymer solids) to the SOC.

### Example 7

### Lithography Comparison of Varying PAG Addition

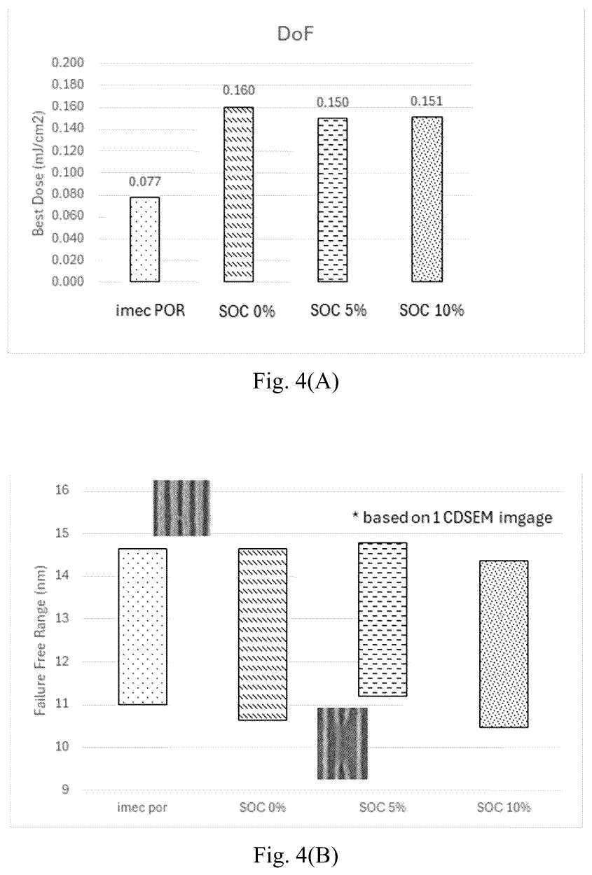

The defect-free depth-of-focus (DOF) and failure-free range of line critical dimension (CD) were analyzed by inspecting the top-down SEM of each die (FIGS. 4(A)-4(B)) produced in Example 6. OptiStack® SOC120 material (Brewer Science, Inc., Rolla, MO) with no PAG (shown as SOC 0%) showed a higher DOF and failure-free range than the IMEC POR (process of record) SOC. With an increasing percentage of PAG (PA-253, Heraeus, Ohio) in the OptiStack® SOC120 material (shown as SOC 5% and SOC 10%), the DOF and failure-free range remained comparable, indicating a high tolerance of PAG incorporation without destroying the litho performance.

### Example 8

### Lithography Comparison of Varying PAG Addition

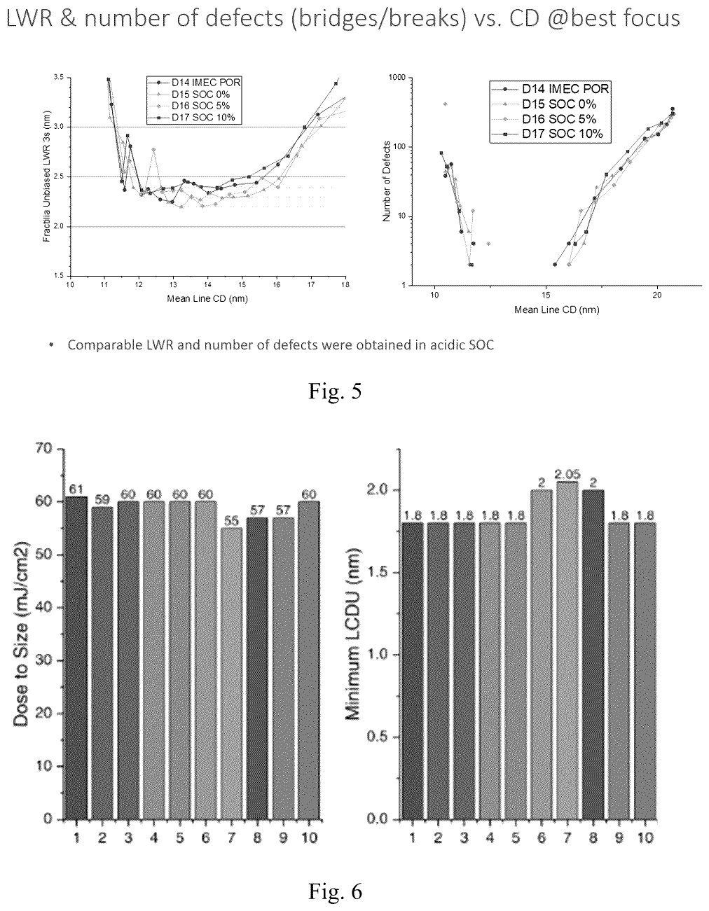

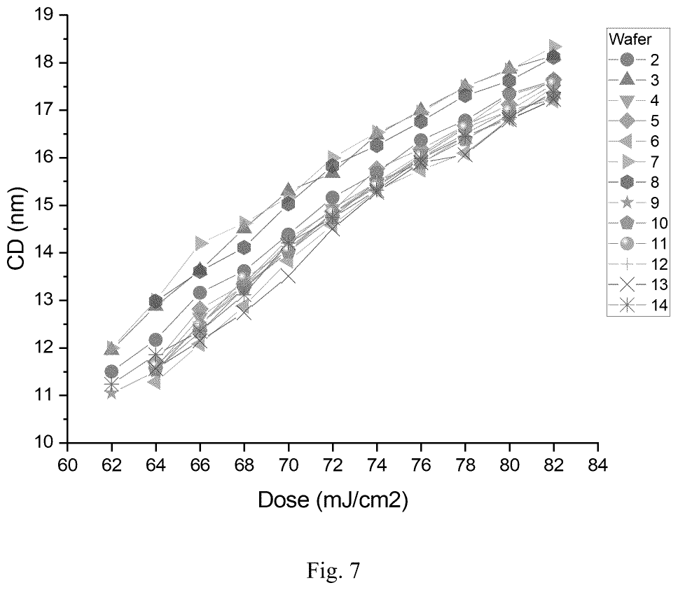

The biased line width roughness (LWR) and the number of defects (bridges and line breaks) of the dies produced in Example 6 were measured at the die at the central focus and the sizing dose by inspecting the top-down SEM. OptiStack® SOC120 material containing 0% PAG (SOC 0%) showed similar LWR and numbers of defects compared to the IMEC POR SOC (FIG. 5). With increasing percentage of PAG in the OptiStack® SOC120 material (SOC 5% and SOC 105), LWR and numbers of defects were comparable, further confirming the robust performance of the acidic SOC.

1. A method of forming a microelectronic structure, said method comprising:
(a) forming an acid-generating layer on a substrate surface, or on one or more intermediate layers optionally present on said substrate surface, said acid-generating layer being formed from an acid-generating composition comprising about 50% by weight or greater carbon on a solids basis, and said acid-generating composition comprising:
(i) a polymer and an acid generator;
(ii) a polymer including recurring monomers comprising an acid-generating group; or
(iii) both (i) and (ii);
(b) forming a hardmask layer on said acid-generating layer;
(c) forming a photoresist layer on said hardmask layer; and
(d) exposing at least a portion of said acid-generating layer to EUV radiation, wherein an acid is generated in said acid-generating layer during and/or after said exposing, and said generated acid diffuses through said hardmask layer and to said photoresist layer.

2. The method of claim 1, wherein said hardmask layer is not acid sensitive.

3. The method of claim 1, wherein said hardmask layer is not physically or chemically altered after said forming (b) and before said forming (c).

4. The method of claim 1, wherein said hardmask layer comprises silicon.

5. The method of claim 1, wherein said hardmask layer comprises less than about 0.5% by weight total of strong acids and generators of strong acids, based upon the total weight of the hardmask layer taken as 100% by weight.

6. The method of claim 1, wherein said polymer is chosen from polystyrene, functionalized polystyrene derivatives, polysulfones, polyethersulfones, poly(ether ether ketone)s, polycarbonates, epoxies, novolacs, polyimides, polyphenols, polyacrylates, or combinations thereof.

7. The method of claim 1, wherein one or both of said acid generator or acid-generating group are chosen from onium salts, substituted forms of onium salts, triazines, or combinations thereof.

8. The method of claim 1, wherein one or both of said acid generator or acid-generating group are chosen from tris(trifluoromethylsulfonyl) methide, triphenyl sulfonium perfluorosulfonates, alkyl-substituted triphenyl sulfonium perfluorosulfonates nonaflates, tris(4-tert-butylphenyl)sulfonium perfluoro-1-butanesulfonate, N-hydroxynaphthalimide triflate, N-hydroxy-5-norbornene-2,3-dicarboximide perfluoro-1-butanesulfonate), 2-methyl-2-(2′-furylethylidene)-4,6-bis(trichloromethyl)-1,3,5-triazine, 2-[(4′-methoxy)styryl]-4,6-bis(trichloromethyl)-1,3,5-triazine, (4-hydroxyphenyl)dimethylsulfonium hexafluorophosphate, (4-(tert-butyl)phenyl)diphenylsulfonium 2-(4-(adamantan-1-yl)-1,1,2,2-tetrafluorobutoxy)-1,1,2,2-tetrafluoroethane-1-sulfonate, N-hydroxy-5-norbornene-2,3-dicarboximide perfluoro-1-butanesulfonate, triphenylsulfonium salt with tris[(trifluoromethyl)sulfonyl]methane, [4-(octyloxy)phenyl](phenyl)iodonium hexafluoroantimonate, triphenylsulfonium hexafluoroantimonate, 2-(4-methoxyphenyl)-4,6-bis(trichloromethyl)-1,3,5-triazine, alkyl-substituted triphenyl sulfonium tetrakis(pentafluorophenyl)borates, or combinations thereof.

9. The method of claim 1, wherein said hardmask layer has an average thickness of about 5 nm to about 50 nm.

10. The method of claim 1, wherein said photoresist has an average thickness of about 20 nm to about 60 nm.

11. The method of claim 1, wherein said photoresist is a chemically amplified resist.

12. The method of claim 1, wherein said forming (a) is carried out without exposing said acid-generating layer to UV radiation.

13. The method of claim 1, wherein:
said acid-generating layer comprises an upper surface;
said hardmask layer is on said upper surface of said acid-generating layer, forming an interface between said acid-generating layer and said hardmask layer; and
during one or both of said forming (a) or said forming (b), said acid generator or said acid-generating group diffuses toward the upper surface of said acid-generating layer.

14. The method of claim 13, wherein:
said hardmask layer comprises an upper surface;
said photoresist layer comprises a polymer and is on said upper surface of said hardmask layer;
during said exposing (d), said acid generator or said acid-generating group generates an acid; and
during said exposing (d), after said exposing (d), or both, said acid diffuses across said interface, through said hardmask layer to said upper surface of said hardmask layer and to said photoresist layer, causing at least some of said polymer in said photoresist layer to undergo a photochemically induced reaction.

15. The method of claim 1, wherein:
said acid generator comprises a photoacid generator;
said acid-generating group comprises a photoacid-generating group; and
said hardmask layer:
is not acid sensitive;
comprises less than about 0.5% by weight total of strong acids and generators of strong acids, based upon the total weight of the hardmask layer taken as 100% by weight; and
is not physically or chemically altered after said forming (b) and before said forming (c).

16. The method of claim 15, wherein:
said hardmask layer has an average thickness of about 5 nm to about 50 nm; and
said photoresist has an average thickness of about 20 nm to about 60 nm.

17. The method of claim 16, wherein said photoresist is a chemically amplified resist.

18. A microelectronic structure comprising:
a substrate having an unpatterned surface;
optionally one or more unpatterned intermediate layers other than a dielectric layer on said substrate surface;
an acid-generating layer on said substrate surface, or on said one or more intermediate layers, if present, said acid-generating layer comprising about 50% by weight or greater carbon based on the weight of the acid-generating layer taken as 100% by weight, and said acid-generating layer comprising:
(i) a polymer and a photoacid generator;
(ii) a polymer including recurring monomers comprising a photoacid-generating group; or
(iii) both (i) and (ii);
a hardmask layer on said acid-generating layer, said hardmask layer comprising less than about 0.5% by weight total of strong acids and generators of strong acids, based on the weight of the hardmask layer taken as 100% by weight; and
a photoresist layer on said hardmask layer.

19. The microelectronic structure of claim 18, wherein said photoresist layer comprises a chemically amplified resist.

20. The microelectronic structure of claim 18, wherein:
said acid generator comprises a photoacid generator;
said acid-generating group comprises a photoacid-generating group; and
said hardmask layer:
is not acid sensitive; and
has an average thickness of about 5 nm to about 50 nm; and
said photoresist has an average thickness of about 20 nm to about 60 nm.
